(19) United States
(12) Patent Application Publication
(10) Pub. No.: US 2004/0085729 A1
(43) Pub. Date: May 6, 2004

(54) Heat dissipating fan

(76) Inventor: Jen-Cheng Lin, Chung-Ho City (TW)

Correspondence Address: VENABLE, BAETJER, HOWARD AND CIVILETTI, LLP, P.O. BOX 34385, WASHINGTON, DC, 20043-9998, US

(21) Appl. No.: 10/286,860

(22) Filed: Nov. 4, 2002

(51) Int. Cl. H05K 7/20

(52) U.S. Cl. 361/695

(57) ABSTRACT

A heat dissipation fan includes a cylindrical housing with an opening defined in a bottom surface of the cylindrical housing for communicating with the heat sink. Multiple fan blades are rotatably mounted inside the cylindrical housing to drive air flow to flow through the opening. A motor is mounted inside the cylindrical housing to drive rotation of the fan blades. The rotation of the fan blades by the motor is able to drive air flow through the opening to dissipate heat in the heat sink.

### BACKGROUND OF THE INVENTION

1. Field of the Invention

The present invention relates to a heat dissipating fan, and more particularly to a centrifugal fan applied to a heat sink so as to dissipate heat effectively.

2. Description of Related Art

With reference to FIGS. 4 and 5, a conventional heat dissipating fan (60) in combination with a heat sink (50) is shown. The combination of the heat dissipating fan (60) and the heat sink (50) normally is used with a central processing unit (CPU) (70). As well known in the computer art, when an electronic apparatus is in operation, the CPU (70) generates heat. The high temperature caused by the CPU (70) mainly is dissipated by the combination of the heat dissipating fan (60) and the heat sink (50). Again, the central portion of the CPU (70) generates the most heat so that the temperature in the central portion of the heat sink (50) is the highest among all of the areas in the heat sink (50), wherein the dashed lines show the temperature in the heat sink (50) caused by the CPU (70).

It is noted that the heat dissipating fan (60) has a fan shaft bracket (61) and fan blades (62) radially extending from a center of the fan shaft bracket (61). Therefore, when the heat dissipating fan (60) of this kind is in use, air flow comes from the rotation of the fan blades (62) which drive the air to flow downward to cool down the heat sink (50). However, as shown in the arrows in FIG. 5, the central portion of the heat dissipating fan (60) literally has not much air flow due to the distribution of the fan blades (62). Accordingly, the heat dissipating effect to the heat sink (50) is not as good as expected.

To overcome the shortcomings, the present invention tends to provide an improved heat dissipating fan to mitigate and obviate the aforementioned problems.

### SUMMARY OF THE INVENTION

The primary objective of the present invention is to provide an improved heat dissipating fan with a cylindrical housing, multiple fan blades rotatably mounted inside the cylindrical housing and an opening defined in a bottom face of the cylindrical housing so that when the fan blades rotate in the cylindrical housing, the air flow driven by the rotation of the fan blades is able to be directed to the opening to effectively dissipate the heat in the central portion of the heat sink.

Other objects, advantages and novel features of the invention will become more apparent from the following detailed description when taken in conjunction with the accompanying drawings.

### BRIEF DESCRIPTION OF THE DRAWINGS

FIG. 1 is a perspective view of the heat dissipating fan of the present invention;

FIG. 2 is a perspective view of the application of the heat dissipation fan with a heat sink;

FIG. 3 is a schematic view showing the heat dissipation effect of the heat dissipation fan of the present invention;

FIG. 4 is a perspective view of a conventional heat dissipation fan in combination of a heat sink; and

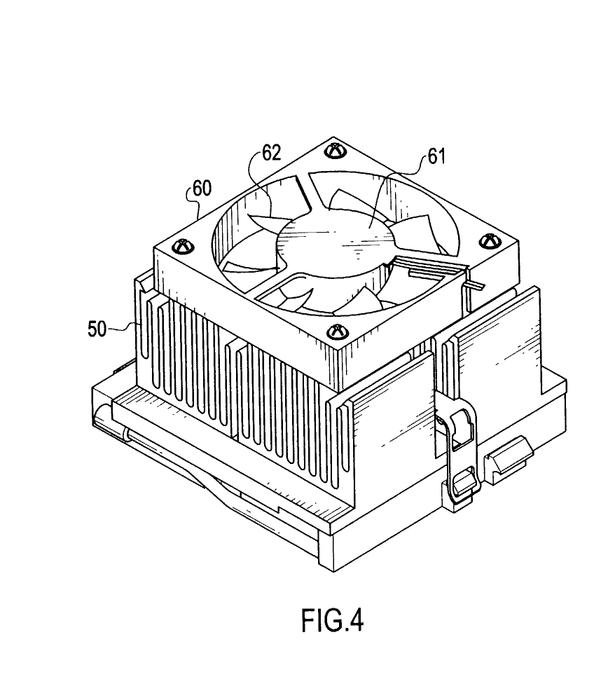

FIG. 5 is a schematic view of the heat dissipation effectiveness of the conventional heat dissipation fan.

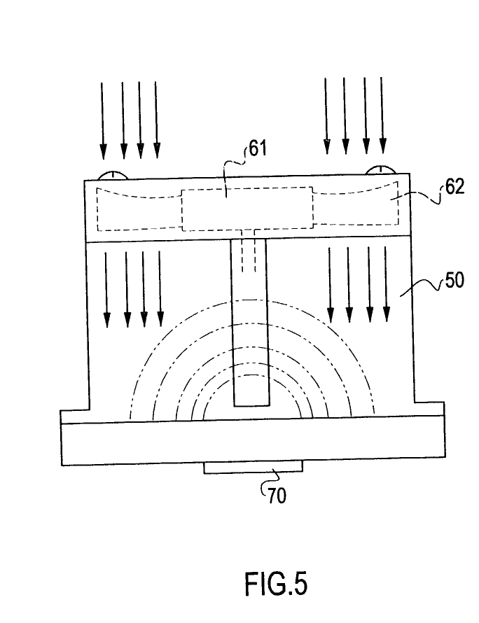

### DETAILED DESCRIPTION OF THE PREFERRED EMBODIMENT

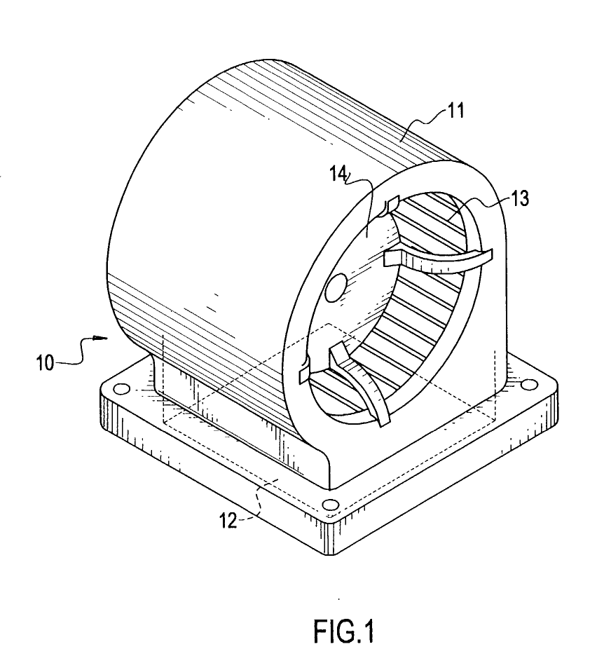

With reference to FIG. 1, the heat dissipation fan (10) in accordance with the present invention has a cylindrical housing (11) with two open ends, an opening (12) defined in a bottom surface of the cylindrical housing (11) and multiple fan blades (13) rotatably mounted inside the cylindrical housing (11) and a motor (14) in the cylindrical housing (11) to drive the fan blades (13).

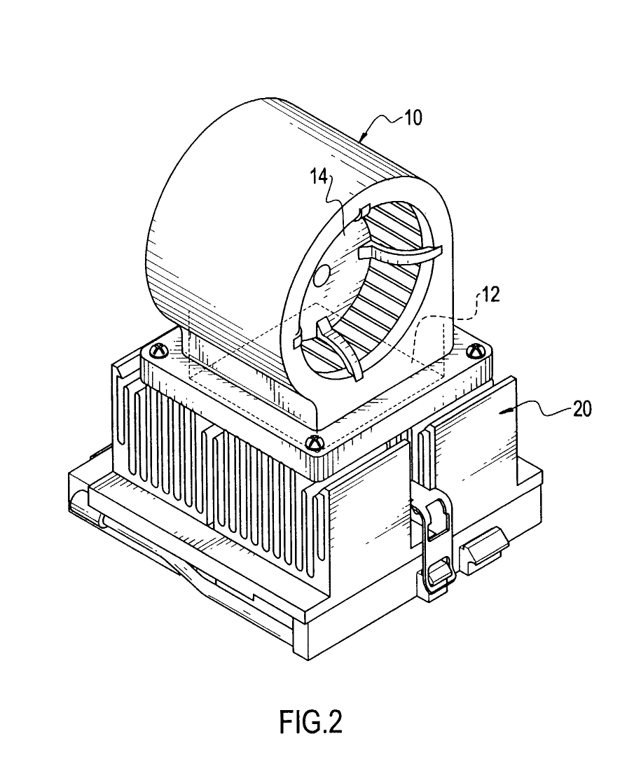

With reference to FIG. 2, when the heat dissipation fan (10) of the present invention is used in combination with a heat sink (20), the heat dissipation fan (10) is securely mounted on top of the heat sink (20) with the opening (12) corresponding to and communicating with the heat sink (20).

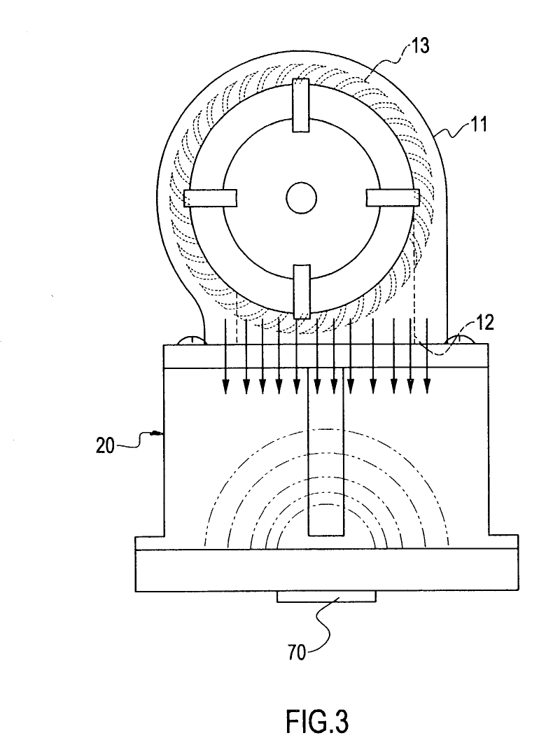

With reference to FIG. 3, after the heat dissipation fan (10) is in operation, the air flow driven by the rotation of the fan blades (13) is able to flow directly through the opening (12) to dissipate the heat in the heat sink (20). Because the size of the opening (12) covers substantially the entire area where the CPU (70) is mounted, the heat generated by the operation of the CPU (70) is able to be effectively dissipated.

That is, when changing the conventional vane-axial fan to a centrifugal fan with an opening to direct the air flow directly to the heat sink (20), the heat dissipation effectiveness is greatly increased. Furthermore, since the dimension of the centrifugal fan is the same as that of the vane-axial fan, there is no need to make any modification so that no cost is incurred due to the change of the heat dissipating fan.

Furthermore, the following is a comparison between the conventional axial fan and the centrifugal fan of the present invention, which shows that the heat dissipation effect is increased.

The conventional vane-axial fan blows the heat from the CPU. However, because the fan motor is mounted on the center of the vane-axial fan, the maximum wind flux and pressure is not on the center of the fan, instead, is on the outer edges of the fan blades, which directs most of the wind toward a place other than the place where the CPU is mounted. Therefore, the heat dissipation effect is greatly reduced.

The centrifugal fan of the present invention has a design to allow the inflow of the air vertical to the outflow of the air and to direct the air inflow directly to the center of the CPU such that the heat dissipation effect is effective.

Cause and process of the experiment: using the flow of the centrifugal fan to dissipate the heat in the heat sink from the CPU;

Process:

1. A relay plate is mounted at the bottom of the centrifugal fan so that the wind is able to blow directly to the center of the CPU to have the basic required effects.

2. Material is added to the inside of the fan housing to direct the wind to the center of the centrifugal fan to increase the heat dissipation effect.

3. Design and process of the experiment:

3.1 Observation of the wind field of the centrifugal fan: The prototype centrifugal fan is not able to flow directly to the heat sink center as expected. Instead, an angle exists between the wind flow and the output of the fan, so that the wind can not effectively dissipate the heat.

3.2 Using the relay plate to direct the wind and the effect thereof: The relay plate is able to direct the wind to the center of the heat sink so that the heat from the CPU is able to be dissipated effectively.

3.3 Test result:

3.3.1 Delta Electronics, Inc. AFB0612VHC, 5400RPM60×60

| Voltage | Current1 | Current2 | Current3 | AllCurrent | Power |
|---|---|---|---|---|---|
| 1.744 | 14.3 | 12.8 | 14.75 | 41.85 | 72.986 |

| Power | Tjunction | Tambient | Thermal resistance |
|---|---|---|---|
| 72.9864 | 82 | 30.6 | 0.7042 |

3.3.2 Blower 5400RPM (Yuan Hsan Tech.) 9.6V 70×70 and blower is horizontal to the Fin of the Heatsink, Blowerwith a displacement of 11.28 mm

| Voltage | Current1 | Current2 | Current3 | AllCurrent | Power |
|---|---|---|---|---|---|
| 1.744 | 14.36 | 11.79 | 14.54 | 40.69 | 70.963 |

| Tjunction | Tambient | Thermal resistance | Reduce | |
|---|---|---|---|---|
| 80 | 31.4 | 0.6848 | temperature | 3.5° C. |

3.3.3 Blower 5400RPM (Yuan Hsan Tech.) 9.6V 70×70 and blower is horizontal to the Fin of the Heatsink; Blower with a displacement of 14.28 mm

| Voltage | Current1 | Current2 | Current3 | AllCurrent | Power |
|---|---|---|---|---|---|
| 1.744 | 14.4 | 12.94 | 14.49 | 41.83 | 72.95152 |

| Tjunction | Tambient | Thermal resistance | Reduce | |
|---|---|---|---|---|
| 79 | 32.6 | 0.636 | temperature | 6.95° C. |

3.3.4 Blower 5400RPM (Yuan Hsan Tech.) 9.6V 70×70 and blower is horizontal to the Fin of the Heatsink; Blower with a displacement of 14.28 mm

| Voltage | Current1 | Current2 | Current3 | AllCurrent | Power |
|---|---|---|---|---|---|
| 1.744 | 14.4 | 12.94 | 14.5 | 41.84 | 72.96896 |

| Tjunction | Tambient | Thermal resistance | Reduce | |
|---|---|---|---|---|
| 82 | 32.1 | 0.6838 | temperature | 3.569° C. |

The blades of the prototype blower No. 2 is horizontal to the fins of the heat sink so that the displacement of the blower from 11.28 to 14.28 mm is able to reduce temperature from 3.5 to 6.95° C.

3.4 Design of the blower to direct the wind to the center of the heat sink without using the relay plate: The interior of the housing of the blower is changed by increasing the interior material so as to change the shape of the interior to direct the wind to the center of the CPU.

3.5 Test of the wind directed to the center of the heat sink:

3.5.1 Effect comparison between the blower and the vane-axial fan both provided with the same skived fin made of brass:

| Heat Sink Type 735-SKIVING | | | | | Heat Sink Type 735-SKIVING | | | | |
|---|---|---|---|---|---|---|---|---|---|
| Fan Type:Blower 3200 RPM, 7060 | | | | | Fan Type:BI-7025-6000 RPM | | | | |
| Input | | | | [symbol] | Input | | | | [symbol] |
| Power | CPU | Ambient | Rth | 0.02° | Power | CPU | Ambient | Rth | 0.02° |
| (W) | Temp. | Temp. | Test | C/W | (W) | Temp. | Temp. | (Test) | C/W |
| 27.03 | 43.80 | 38.33 | 0.20 | | 26.44 | 47.98 | 41.60 | 0.24 | |
| 52.45 | 53.06 | 40.23 | 0.24 | | 52.42 | 57.72 | 44.70 | 0.23 | |
| 77.30 | 60.76 | 41.93 | 0.24 | | 76.48 | 64.66 | 46.80 | 0.23 | |

| Heat Sink Type 735-SKIVING | | | | Heat Sink Type 735-SKIVING | | | |
|---|---|---|---|---|---|---|---|
| Fan Type:Blower 3200 RPM, 7060 | | | | Fan Type:BI-7025-4500 RPM | | | |
| Input | | | | Input | | | |
| Power | CPU | Ambient | Rth | Power | CPU | Ambient | Rth |
| (W) | Temp. | Temp. | Test | (W) | Temp. | Temp. | (Test) |
| 27.03 | 43.80 | 38.33 | 0.20 | 27.39 | 45.66 | 38.55 | 0.26 |
| 52.45 | 53.06 | 40.23 | 0.24 | 55.42 | 55.18 | 41.05 | 0.25 |
| 77.30 | 60.76 | 41.93 | 0.24 | | | | |

After using the same fin, the blower reaches a heat dissipation effect with only 3200 rpm, which the conventional axial fan requires 6000 rpm to reach the same effect (0.23˜0.24=0.23˜0.24). Sometimes, the heat dissipation effect of the blower is even better than that of the axial fan (0.20<0.23˜0.24). The comparison of the blower at 4500 rpm between the axial fan at 4500 rpm exceeds 0.20˜0.24<0.25˜0.26.

The same motor has been used for the blower and the conventional axial fan.

3.5.2 blower radius at the same thermal resistance:

| 731-SKVING(fin height mm) | | | 735-SKVING(fin height 35 mm) | | |
|---|---|---|---|---|---|
| Rth | FAN SPEED | dB (A) | Rth | FAN SPEED | dB (A) |
| 0.34 | 1750 | 23.8/20.85 | 0.34 | 1700 | 22.78/19.75 |
| 0.31 | 2150 | 32.25/27.27 | 0.32 | 2000 | 29.77/25.31 |
| | 2600 | 38.87/33.95 | | 2400 | 35.29/30.22 |
| 0.28 | 2800 | 40.72/36.66 | 0.28 | 2600 | 38.60/33.75 |

Available product on the market (7025,6000 rpm)

| Rth | Fan SPEED | DB (A) |
|---|---|---|
| 0.293922 | 6000 | 46 [symbol] |

At the same thermal resistance, the blower of the present invention only needs 2400-2600, 2800 to reach the same effect by other products at 6000 rpm. Further, the decibel is reduced so that the blower also has an effect of reducing sound pollution.

Advantages of the blower of the invention to direct the wind to the center of the heat sink:

1. Effectively reducing the average temperature on the integrally formed heat sink.

2. Lower rotation speed on the Skived Fin to reach the same effect as that of the conventional fan.

3. Effectively reducing noise by lower rotation speed.

4. Heat dissipation effect is improved regardless of the material of the heat sink.

5. Improved heat dissipation effect by directing wind to the center of the heat sink.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A heat dissipation fan adapted to connect to a heat sink, the heat dissipation fan comprising:
a cylindrical housing with two open ends and an opening defined in a bottom surface of the cylindrical housing for communicating with the heat sink;
multiple fan blades rotatably mounted inside the cylindrical housing to drive air flow to flow through the opening; and
a motor mounted inside the cylindrical housing to drive rotation of the fan blades,
whereby rotation of the fan blades by the motor is able to drive air flow through the opening to dissipate heat in the heat sink.
